(19) United States
(12) Patent Application Publication
(10) Pub. No.: US 2004/0136162 A1
(43) Pub. Date: Jul. 15, 2004

(54) Heat dissipating device for electronic components of electronic control devices

(76) Inventors: Nobuhiro Asai, Aichi-ken (JP); Yoshitami Saito, Aichi-ken (JP)

Correspondence Address: BURNS DOANE SWECKER & MATHIS L L P, POST OFFICE BOX 1404, ALEXANDRIA, VA, 22313-1404, US

(21) Appl. No.: 10/717,522

(22) Filed: Nov. 21, 2003

(30) Foreign Application Priority Data
Nov. 21, 2002 (JP) 2002-338096

(51) Int. Cl. H05K 7/20

(52) U.S. Cl. 361/715; 361/719; 361/707

(57) ABSTRACT

A heat dissipation device for dissipating heat produced by electronic components of an electronic control device is disclosed. The electronic control device includes a circuit board and a protective case. The electronic components are mounted on the circuit board. The case substantially confines the circuit board. The heat dissipation device includes heat conductive terminals. The heat conductive terminals are connected to the circuit board in positions proximate to the respective electronic components, so that the heat of the electronic components is transferred or conducted to the heat conductive terminals. The heat conductive terminals are connected to the case body in order to further conduct the heat to the case body.

This application claims priority to Japanese patent application serial number 2002-338096, the contents of which are incorporated herein by reference.

### BACKGROUND OF THE INVENTION

1. Field of the Invention

The present invention relates to heat dissipating devices for electronic components of electronic control devices, in particular electronic control devices such as in-vehicle electronic control devices, in which a circuit board having electronic components mounted thereon is confined within a case.

2. Description of the Related Art

Japanese Laid-Open Patent Publication No. 10-150283 teaches a known heat-dissipating device for electronic components of an electronic control device. The known heat-dissipating device includes a metal, heat-dissipation layer that is separately disposed within a circuit board, apart from the ordinary copper conductive layers typically formed on the circuit board. First heat conductive portions extend upward from the heat-dissipation layer and are joined to respective electronic components that are mounted on the circuit board. Second heat conductive portions extend downward from the heat-dissipation layer. One end of a metal spring contacts each of the second conductive portions. The heat-dissipating device also includes a heat dissipation plate disposed at the bottom of the interior of a case confining the circuit board. The heat dissipation plate contacts with the other end of each metal spring. In addition, screws are inserted into the circuit board and extend through the heat-dissipation layer. Each screw also contacts the heat dissipating plate at the bottom of the case. Therefore, the heat generated by the electronic components may be conducted to the heat dissipating plate from the heat-dissipating layer via the metal springs and/or the screws. The heat may then be dissipated from the heat dissipating plate.

However, with the known heat-dissipating device, the heat produced by the electronic components may be conducted to the heat-dissipation plate only from the lower side of the heat dissipation layer. Only using the lower side of the heat dissipation layer creates inefficiency in the heat transfer process. Therefore, if the electronic components have generated heat during long periods of use, the inefficiency may result in an excessive ambient temperature within the case.

### SUMMARY OF THE INVENTION

It is accordingly an object of the present invention to teach improved techniques for effectively dissipating heat produced by electronic component(s) that is(are) confined within a relatively sealed environment.

According to one aspect of the present teachings, heat dissipation devices are taught for dissipating heat produced by at least one electronic component(s) of an electronic control device. The electronic control device includes a circuit board and a protective case. The electronic component is mounted on the circuit board. For example, the electronic component may be an integrated circuit (IC), a transistor, a capacitor, a resistor, or any device that generates heat during operation. The protective case separates an interior space and from an outside environment. The circuit board is substantially confined within the interior space of the protective case. The heat dissipation device includes a heat conductive terminal that is connected to the circuit board in a close proximity to the electronic component. The close proximity of the heat conductive terminal allows for less restrictive transfer or conduction of the heat generated by the electronic component into the heat conductive terminal. The other end of the heat conductive terminal is connected to the case in order to facilitate dissipation of the heat to the outside environment.

Therefore, the heat produced by the electronic component may be conducted or transferred to the heat conductive terminal and then conducted or transferred to the protective case via the heat conductive terminal. Once the heat has reached the case, the heat may then be dissipated into the outside environment via the external surface of the protective case. As a result of the heat-dissipation device, excessive increases in the ambient temperature inside of the protective case as well as excessive increases in the temperature of the electronic components may be limited or reduced.

Preferably, the protective case includes a case body and a case cover. The case body is preferably made of metal or some other thermally conductive material. The heat conductive terminal is joined or in contact with the case body. Therefore, a direct pathway is effectively established to allow the heat conducted from the heat conductive terminal to reach the case body for subsequent dissipation to the outside environment.

In another aspect of the present teachings, the heat conductive terminal has a first end portion and a second end portion. The first end portion is connected to the case. The second end portion is inserted into an insertion hole formed in the circuit board so as to be connected to an inner wall of the insertion hole. Therefore, by utilizing the insertion hole, an easy and reliable connection can be made between the heat conductive terminal and the circuit board.

In additional aspect of the present teachings, the heat-dissipating device further includes a first heat conductive layer formed on an inner wall of the insertion hole. In addition, at least one second heat conductive layer is disposed upon or within the circuit board and connected to the first heat conductive layer. Thereby allowing the heat conducted or transmitted from the electronic components to the second heat conductive layer, to be further conducted or transmitted to the heat conductive terminal. As a result, the heat produced by the electronic components can be reliably conducted or transferred to the heat conductive terminal via the first heat conductive layer.

A soldered portion preferably fixes the second end portion of the heat conductive terminal to the first heat conductive layer. In general, the electronic components are soldered to the upper surface of the circuit board. Therefore, the process for joining the heat conductive terminal to the first heat conductive layer can be performed at the same time the electronic components are soldered. As a result, the efficiency of manufacturing is improved by using the same process for more than one operation.

Alternatively, the second end portion of the heat conductive terminal may be fixed in position relative to the insertion hole via first and second protrusions that contact a top and bottom surface of the circuit board. The second end portion directly contacts the first heat conductive layer. This allows the process for joining the heat conductive terminal to the circuit board to be made without using the soldering process and without requiring an additional joint member. The operation for joining the heat conductive terminal to the circuit board in this aspect can be easily and simply performed.

In a further aspect of the present teachings, the second heat conductive layers include a top heat conductive layer, at least one intermediate heat conductive layer, and a bottom heat conductive layer that are disposed on a top surface, an intermediate region, and a bottom surface of the circuit board, respectively. Therefore, the heat of the electronic component can be readily conducted from the various second heat conductive layers to the heat conductive terminal.

In a further aspect of the present teachings, the circuit board further includes a through-hole formed in the circuit board and extends throughout the thickness of the circuit board. The through-hole is disposed opposite to the heat generating electronic component. A first electrically conductive layer is formed on an inner wall of the through-hole. Furthermore, the circuit board includes a plurality of second electrically conductive layers. The second electrically conductive layers include a top electrically conductive layer, at least one intermediate electrically conductive layer, and a bottom electrically conductive layer that are disposed on a top surface, an intermediate region, and a bottom surface of the circuit board, respectively. At least two of the second electrical conductive layers are connected to each other via the first electrical conductive layer. Therefore, the heat generated by the electronic components may be directly conducted to at least two of the second electrically conductive layers and then may be directly or indirectly conducted to the corresponding second heat conductive layers. By utilizing the second electrically conductive layers that are naturally provided to the circuit board, the conduction of heat from the electronic components to the second heat conductive layers can be efficiently and reliably performed.

Preferably, the top electrically conductive layer is connected to at least one of the intermediate electrically conductive layers as well as connected to the bottom electrically conductive layer. This allows the heat generated by the electronic component to be conducted to top electrically conductive layer and then via the first electrically conductive layer further conducted to at least one of the intermediate electrically conductive layers as well as to the bottom electrically conductive layer.

In a further aspect of the present teachings, the top heat conductive layer and the top electrical conductive layer are preferably made of the same material and are formed simultaneously with each other. Similarly, the intermediate heat conductive layer and the intermediate electrical conductive layer are also preferably made of the same material and are formed simultaneously with each other. Additionally, the bottom heat conductive layer and the bottom electrical conductive layer are preferably made of the same material and are formed simultaneously with each other. Therefore, all of the second heat conductive layers may be formed at the same time that the corresponding second electrically conductive layers are formed. As a result, the second heat conductive layers can be readily formed without any additional steps.

In a further aspect of the present teachings, the top heat conductive layer and the top electrically conductive layer are electrically insulated from each other. Similarly, the intermediate heat conductive layer and the intermediate electrical conductive layer are also electrically insulated from each other. Additionally, the bottom heat conductive layer and the bottom electrical conductive layer are electrically insulated from each other. Therefore, even if the top electrically conductive layer has a potential voltage, the potential voltage may not be transferred to the second heat conductive layers and the case connected thereto. In other words, the case can be kept grounded. As a result, if an exterior grounded member occasionally contacts the case, no potential voltage should be generated between the grounded member and the case and no electrical shock may be received by the either the grounded member or the case.

In further aspect of the present teachings, electronic control devices are taught that include the above various aspects of the heat dissipating devices. The various aspects of the heat dissipating devices can be used either singularly or combined in a manner appropriate to the specific electronic control device.

### BRIEF DESCRIPTION OF THE DRAWINGS

Additional objects, features, and advantages, of the present invention will be readily understood after reading the following detailed description together with the claims and the accompanying drawings, in which:

FIG. 1 is a cross sectional view of a first representative electronic control device; and

FIG. 2 is a view similar to FIG. 1 but showing a second representative electronic control device; and

FIG. 3 is a modification of a joint structure between a terminal insertion hole of a circuit board and a heat conductive terminal of the first representative embodiment.

### DETAILED DESCRIPTION OF THE INVENTION

Each of the additional features and teachings disclosed above and below may be utilized separately or in conjunction with other features and teachings to provide improved heat dissipating devices and methods of manufacturing and using such heat dissipating devices. Representative examples of the present invention, which examples utilize many of these additional features and teachings both separately and in conjunction, will now be described in detail with reference to the attached drawings. This detailed description is merely intended to teach a person of skill in the art further details for practicing preferred aspects of the present teachings and is not intended to limit the scope of the invention. Only the claims define the scope of the claimed invention. Therefore, combinations of features and steps disclosed in the following detailed description may not be necessary to practice the invention in the broadest sense, and are instead taught merely to particularly describe representative examples of the invention. Moreover, various features of the representative examples and the dependent claims may be combined in ways that are not specifically enumerated in order to provide additional useful embodiments of the present teachings.

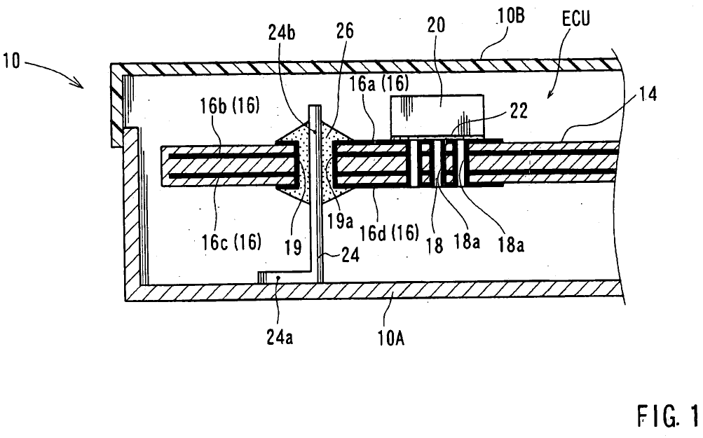

A first representative embodiment will now be described with reference to FIG. 1, which shows a first representative electronic control device that is configured as an in-vehicle electronic control device, such as a brake control device, adapted to be mounted within a vehicle, e.g., for example, powered and unpowered transportation or recreational device, such as an automobile or trailer. The representative electronic control device includes an ECU (electronic control unit) that is sealingly confined within a protective case 10. The ECU has a printed circuit board 14 that is structurally built up into a multi-layered configuration. Various electronic components 20 (only one electronic component 30 is shown in FIG. 1), such as ICs, transistors, resistors, capacitors, and other heat generating components, are mounted to the upper surface of the circuit board 14 (top surface as viewed in FIG. 1).

The protective case 10 includes a case body 10A and a case cover 10B. The case body 10A is made of a thermally conductive material, preferably metal, and the case cover 10B is made of metal or synthetic resin. Although not shown in the drawings, a metal actuator block may be assembled onto the outer side (the lower most side as viewed in FIG. 1), if the electronic control device is configured as a brake control device for controlling the hydraulic pressure to vehicle brake devices (not shown). The actuator block may be made of metal, e.g., aluminum alloy, and may have a plurality of solenoids mounted thereon.

The multi-layered circuit board 14 is manufactured by stacking and bonding a plurality of electrical insulation plates, e.g., epoxy plates, each having an electrically conductive film, e.g., a copper film, attached to one or both sides in a known manner. In this representative embodiment, the circuit board 14 has a total of four conductive films 16 comprising a top conductive film 16a, two intermediate conductive films 16b and 16c and a bottom conductive film 16d. Thus, the top conductive film 16a, the intermediate conductive films 16b and 16c and the bottom conductive film 16d form a top conductive layer, intermediate conductive layers and a bottom conductive layer of the circuit board 14, respectively. The four conductive films 16 can be electrically conductive, thermally or heat conductive, or both. The top conductive film 16a is configured as a patterned film or a wired film. The electrical components 20 are mounted to the top conductive film 16a at predetermined positions via respective soldered portions 22. The intermediate conductive films 16b and 16c extend substantially all over the entire area defined by circuit board 14. One of the two intermediate conductive films shown, 16b and 16c, is connected to a power source (not shown) while the other is connected to the ground.

A plurality of through-holes 18 are formed to extend through the thickness of the circuit board 14 at various positions in close proximity to each heat generating electronic component 20A. An electrically conductive layer 18a is formed on an inner wall of each of the through-holes 18 by an appropriate technique, such as chemical copper plating, such that the top conductive film 16a and the bottom conductive film 16d are electrically connected to each other via the electrically conductive layer 18a. Alternatively, the electrically conductive layer 18a can be used to connect any combination of the top and bottom conductive films 16a and 16d and the intermediate conductive films 16b and 16c. The various electrical connections between the conductive films 16a to 16d can be selectively determined in response to the intended wiring for the respective electronic components 20.

A plurality of terminal insertion holes 19 (only one terminal insertion hole 19 is shown in FIG. 1) are formed in the circuit board 14 in positions proximate to respective electrical components 20. The terminal insertion holes 19 have a diameter that is slightly greater than the diameter of the through-holes 18. In addition, a heat conductive layer 19a is formed on the inner wall of the terminal insertion hole 19, so that the electrically conductive films 16 are connected to each other via the heat conductive layer 19a. The heat conductive layer 19a may be made of copper and may be formed by a chemical copper plating process similar to the electrically conductive layer 18a of the through hole 18. Although the heat conductive layer 19a may be also electrically conductive, electrical conductivity is not essential to the heat conductive layer 19a.

A plurality of heat conductive terminals 24 have lower base portions 24a that may be fixed to the inner bottom surface of the case body 10A by using an appropriate bolding technique, e.g., welding, crimping, riveting, gluing, and screw-fastening. The heat conductive terminals 24 are preferably made of metal plates, e.g., aluminum alloy plates, which are bent to have a substantially L-shaped configuration. The heat conductive terminals 24 have upper end portions 24 that are inserted into the respective terminal insertion holes 19 of the circuit board 14. The heat conductive terminals 24 are joined to the heat conductive layers 19a of the inner walls of the terminal insertion holes 19 preferably via soldered portions 26. Again, in order to emphasize, although the heat conductive terminals 24 and the soldered portions 26 may be electrically conductive, they are primarily intended for conduction of heat. The circuit board 14 may be supported within the case body 10A via support members (not shown) that are made of an insulating material such as resin, so that the circuit board 14 may be electrically insulated from the case body 10A.

According to the representative electronic control device shown in FIG. 1, the heat produced by the electronic components 20 mounted on the circuit board 14 is conducted to the top conductive film 16a of the group of conductive films 16, and then via the electrically conductive layers 18a to the inner conductive films 16b and 16c as well as to the bottom conductive film 16d. The heat conducted to the conductive films 16 may be further conducted to the metal case body 10A via the heat conductive terminals 24 and the soldered portions 26. The films can all be either thermally conductive, electrically conductive, or both. Because the case body 10A has a high thermal conductivity and may also have a large heat sinking capacity, the heat generated by the electrical components 20 may be conducted to the case body 10A and subsequently be effectively dissipated to the outside environment. As a result, increases in the ambient temperature within the interior of the protective case 10 and increases in the temperature of the electronic components 20 can be effectively inhibited or minimized. Specifically, the heat dissipation efficiency is further improved because the heat generated by the electronic components 20 or the ambient heat contained within the case 10 is transferred or conducted to all of the conductive films 16 of the circuit board 14. The total amount of area represented by all of the conductive films facilitates the transfer or conduction of heat from the electronic components 20.

The connection of the heat conductive terminals 24 to the circuit board 14 at the respective terminal insertion holes 19 may be made according to the following steps. First, the circuit board 14 is set within the case body 10A, the heat conductive terminals 24 having been bonded previously to the case body 10A, so that the terminal insertion holes 19 receive the upper end portions 24b of the respective heat conductive terminals 24. Then, the electronic components 20 and other parts are soldered to the top conductive film 16a of the circuit board 14. At the same time, the upper end portions 24b of the heat conductive terminals 24 are soldered to the inner wall of the respective terminal insertion holes 19. Preferably, immersing only the region of the top conductive film 16a of the circuit board 14 after the parts including the electronic components 20 are provisionally mounted to the circuit board 14 performs the soldering process of the electronic components 20. With the immersing type of soldering process, the soldering of the heat conductive terminals 24 to the inner walls of the terminal insertion holes 19 can be made simultaneously with the soldering process of the electronic components 20.

If the representative electronic control device is configured to have an actuator block (not shown) that is mounted to the outside of the case body 10A (the lower side as viewed in FIG. 1), the lower base portions 24a of the heat conductive terminals 24 may be extended to the outside surface of the actuator block through the bottom wall of case body 10A so as to allow connection to the actuator block. The actuator block may be made of material, e.g. aluminum alloy, which has a high capacity for thermal heat conductivity. Therefore, the heat generated by the electronic components 20 may be conducted to the actuator block via the heat conductive terminals 24 and may then be effectively dissipated to the outside environment from the actuator block.

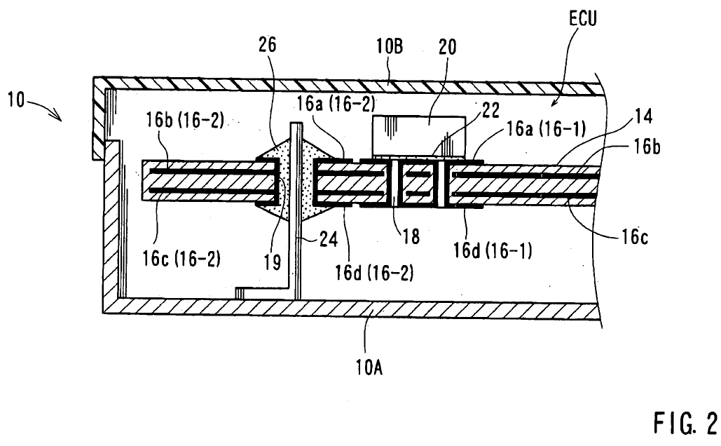

A second representative embodiment will now be described in connection with FIG. 2. The second representative embodiment is a modification of the first representative embodiment. Therefore, in FIG. 2, identical members are given the identical reference numerals as in FIG. 1 and no initial explanation of these members will be repeated.

A second representative electronic control device shown in FIG. 2 includes a first group of electrically conductive films 16-1 and a second group of heat conductive films 16-2. Each group of conductive films preferably comprises copper films similar to the conductive films 16 of the first representative embodiment. However, the first and second groups of conductive films are not electrically connected to each other. The first group 16-1 includes a top electrically conductive film 16a (16-1), intermediate electrically conductive films 16b (16-1) and 16c (16-1), and a bottom electrically conductive film 16d (16-1), that correspond to the top conductive film 16a, the intermediate conductive films 16b and 16c, and the bottom conductive film 16d, of the first representative embodiment, respectively. Similarly, the second group 16-2 includes a top heat conductive film 16a (16-2), intermediate heat conductive films 16b (16-2) and 16c (16-2), and a bottom heat conductive film 16d (16-2), that correspond to the top conductive film 16a, the intermediate conductive films 16b and 16c, and the bottom conductive film 16d of the first representative embodiment, respectively. The top conductive films 16a (16-1) and 16a (16-2), the intermediate conductive films 16b (16-1) and 16b (16-2), the intermediate conductive films 16c (16-1) and 16c (16-2), and the bottom conductive films 16d (16-1) and 16d (16-2) are preferably all made of the same material, i.e., copper, and are all formed at the same time with each other.

As will be seen from FIG. 2, the electrically conductive films 16-1 of the first group are selectively connected to the electrically conductive layers 18a of the through-holes 18 formed in the circuit board 14. However, the heat conductive films 16-2 of the second group are not connected to the electrically conductive layers 18a. Therefore, even if an electric potential forms on any of the electrically conductive films 16-1 of the first group, insulated heat conductive films 16-2 of the second group and the case body 10A are kept grounded.

According to the second representative embodiment, the heat dissipation efficiency of the electronic components 20 may be reduced in comparison with the first representative embodiment, because the heat generated by the electronic components 20 is not directly conducted to the heat conductive terminals 24 and further to the case body 10A. However, the heat generated by the electronic components 20 may be conducted to the heat conductive films 16-2 via the electrical insulation material used to form the circuit board 14. In addition, the heat of the electronic components 20 may be radiated or transferred to the heat conductive terminals 24 and case body 10A via the ambient air within the protective case 10. Therefore, the heat may still be effectively dissipated from the case body 10A to the outside environment. Further, because the heat conductive films 16-2 of the second group are not required to conduct electricity, they may be replaced with any material having a high capacity for thermal or heat conductivity without the limitation of having to duplicate the electrical conductivity of the material used in the electrically conductive films 16-1.

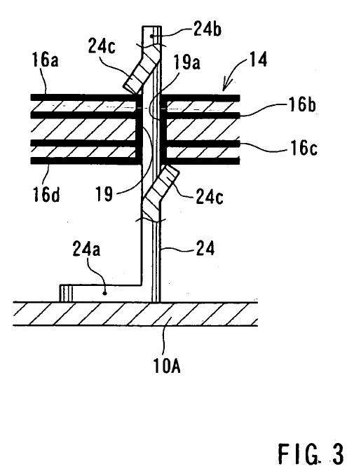

A modification of a joint structure between the terminal insertion hole 19 and the heat conductive terminal 24 of the first representative embodiment will now be described with reference to FIG. 3. In FIG. 3, identical members are given the same reference numerals as in FIG. 1 and an initial explanation of these members will not be performed.

In the modification shown in FIG. 3, each of the soldered portions 26 is replaced with upper and lower protrusions 24c that are preferably formed by cutting and bending parts of the upper end portion 24b of the heat conductive terminal 24. The protrusions 24c may also be formed by a variety of manufacturing methods, including stamping, punching, or deforming. In addition, even though FIG. 3 shows the protrusions opposing each other in direction, the protrusions could be in the same direction to possibly bias the heat conductive terminal 24 toward one side of the terminal insertion hole or to aid in formation of the protrusions. The upper and lower protrusions 24c engage the top surface and the bottom surface, respectively, of the circuit board 14. The upper and lower protrusions 24c contact the top conductive film 16a and the bottom conductive film 16d, respectively. The layers may be electrically conductive, thermally or heat conductive, or preferably both. In this modification, the material of the upper end portion 24b of the heat conductive terminal 24 between the upper and lower protrusions 24c, contacts with heat conductive layer 19a formed on the inner wall of the terminal insertion hole 19. Along with this modification, the heat generated by the electronic components 20 may be conducted to the heat conductive terminals 24 via the conductive films 16.

Additionally, the modification of the upper and lower protrusions 24c for the heat conductive terminals may also be applied to the second representative embodiment.

What is claimed is:

1. A heat-dissipation device for dissipating heat produced by at least one electronic component of an electronic control device, wherein the electronic control device includes a circuit board having the electronic component mounted thereon, and a protective case substantially confining the circuit board, the heat dissipation device comprising:
a heat conductive terminal connected to the circuit board in a position proximate to the electronic component, so that the heat of the electronic component is transferred or conducted to the heat conductive terminal;
wherein the heat conductive terminal contacts the protective case in order to thermally conduct the heat to the protective case.

2. A heat-dissipating device as in claim 1, wherein the heat conductive terminal further comprises;
a first end portion connected to the protective case, and
a second end portion inserted into an insertion hole formed in the circuit board so as to be connected to an inner wall of the insertion hole.

3. A heat-dissipating device as in claim 2, further comprising;
a first heat conductive layer formed on the inner wall of the insertion hole, and
at least one second heat conductive layer disposed on or within the circuit board and connected to the first heat conductive layer, so that the heat conducted or transmitted from the electronic component to the at least one second heat conductive layer is further conducted to the heat conductive terminal.

4. A heat-dissipating device as in claim 3, wherein the second end portion of the heat conductive terminal is connected to the first heat conductive layer by a soldered portion.

5. A heat-dissipating device as in claim 4, wherein the at least one second heat conductive layer includes a top heat conductive layer, at least one intermediate heat conductive layer, and a bottom heat conductive layer, that are disposed on a top surface, an intermediate region, and a bottom surface of the circuit board, respectively.

6. A heat-dissipating device as in claim 5, wherein the circuit board further having at least one through hole formed in the circuit board extending throughout the thickness of the circuit board and disposed in close proximity to the electronic component, additionally includes:
a first electrical conductive layer formed on an inner wall of the through-hole; and
a plurality of second electrically conductive layers including a top electrically conductive layer, at least one intermediate electrically conductive layer, and a bottom electrically conductive layer that are disposed on a top surface, an intermediate region, and a bottom surface of the circuit board, respectively, wherein at least two of the second electrical conductive layers are connected to each other via the first electrically conductive layer.

7. A heat-dissipating device as in claim 6, wherein the top electrically conductive layer is connected to at least one of the intermediate electrically conductive layer and the bottom electrically conductive layer, so that the heat produced by the electronic component is conducted to the top electrically conductive layer and then to the at least one of the intermediate electrically conductive layer and to the bottom electrically conductive layer, via the first electrically conductive layer.

8. A heat-dissipating device as in claim 7, wherein the top heat conductive layer and the top electrically conductive layer are made of the same material and are formed simultaneously with each other.

9. A heat-dissipating device as in claim 8, wherein the top heat conductive layer and the top electric ally conductive layer are separated from each other electrically.

10. A heat-dissipating device as in claim 7, wherein the intermediate heat conductive layer and the intermediate electrically conductive layer are made of the same material and are formed simultaneously with each other.

11. A heat-dissipating device as in claim 10, wherein the intermediate heat conductive layer and the intermediate electrical conductive layer are separated from each other electrically.

12. A heat dissipating device as in claim 7, wherein the bottom heat conductive layer and the bottom electrically conductive layer are made of the same material and are formed simultaneously with each other.

13. A heat-dissipating device as in claim 12, wherein the bottom heat conductive layer and the bottom electrical conductive layer are separated from each other electrically.

14. A heat-dissipating device as in claim 1, wherein the protective case includes a case body and a case cover, the case body is made of metal, and the circuit board is mounted to and within the case body.

15. An electronic control device comprising the heat-dissipating device as in claim 14.

16. A heat-dissipating device as in claim 3, wherein the second end portion further includes;
a first protrusion contacting a top surface of the circuit board,
a second protrusion contacting a bottom surface of the circuit board, and
wherein the heat conductive terminal is fixed in position relative to the insertion hole via the first and second protrusions, and
wherein the second end portion directly contacts the first heat conductive layer.

17. A heat-dissipating device as in claim 16, wherein the at least one second heat conductive layer includes a top heat conductive layer, at least one intermediate heat conductive layer, and a bottom heat conductive layer, that are disposed on a top surface, an intermediate region, and a bottom surface of the circuit board, respectively.

18. A heat-dissipating device as in claim 17, wherein the circuit board further having at least one through hole formed in the circuit board extending throughout the thickness of the circuit board and disposed in close proximity to the electronic component, additionally includes:
a first electrical conductive layer formed on an inner wall of the through-hole; and
a plurality of second electrically conductive layers including a top electrically conductive layer, at least one intermediate electrically conductive layer, and a bottom electrically conductive layer that are disposed on a top surface, an intermediate region, and a bottom surface of the circuit board, respectively, wherein at least two of the second electrical conductive layers are connected to each other via the first electrically conductive layer.

19. A heat-dissipating device as in claim 18, wherein the top electrically conductive layer is connected to at least one of the intermediate electrically conductive layer and the bottom electrically conductive layer, so that the heat produced by the electronic component is conducted to the top electrically conductive layer and then to the at least one of the intermediate electrically conductive layer and to the bottom electrically conductive layer, via the first electrically conductive layer.

20. A heat-dissipating device as in claim 19, wherein the protective case includes a case body and a case cover, the case body is made of metal, and the circuit board is mounted to and within the case body.
